(19) United States
(12) Patent Application Publication
(10) Pub. No.: US 2007/0177963 A1
(43) Pub. Date: Aug. 2, 2007

(54) End effector for transferring a wafer

(76) Inventors: Chee Wee Tang, Singapore (SG); Wee Fong Chow, Singapore (SG); Wai Leong Yip, Singapore (SG); Hong Kiat Chia, Singapore (SG)

Correspondence Address: MITCHELL P. BROOK;C/O LUCE, FORWARD, HAMILTON & SCRIPPS LLP, 11988 EL CAMINO REAL, SUITE 200, SAN DIEGO, CA, 92130, US

(21) Appl. No.: 11/345,970

(22) Filed: Feb. 1, 2006

(51) Int. Cl. H01L 21/677

(52) U.S. Cl. 414/217

(57) ABSTRACT

An end effector for transferring a wafer, a method of re-sitting a wafer in a wafer cassette, and a method of calibrating positioning of an end effector for wafer-pick. The end effector comprises a blade for supporting the wafer during transfer, and at least one engagement element coupled to the blade, the engagement element protruding from the blade for engaging the wafer during insertion of the blade into a wafer cassette for re-sitting of the wafer in the cassette.

### FIELD OF THE INVENTION

The present invention relates broadly to an end effector for transferring a wafer, to a method of re-sitting a wafer in a wafer cassette, and to a method of calibrating positioning of an end effector for wafer-pick.

### BACKGROUND

During wafer fabrication in the semiconductor industries, wafers are typically transferred or transported from one processing station to another by using a robotic arm and end effector. The end effector typically comprises a blade on which the wafer “sits” during transportation. Blade fences are located at the periphery of the blade and act as a boundary for the circumference of the wafer to prevent the wafer from falling off the blade during transportation. A vacuum or mechanical chuck may also be incorporated for securing the wafer on the blade.

When a wafer in the cassette “sits” out of position in relation to its pocket, one problem may arise that the wafer may rest in an abnormal or unsafe position after being picked-up by the end effector such that the wafer is out of the gripping tolerance during transfer to or between processing stations. This may give rise to wafer slip. To overcome this problem, an existing solution is to implement an additional transfer sequence or system to “re-sit” the out-of-position wafer prior to the end effector pick-up. However, implementing the additional transfer sequence or system typically incurs additional cost to the manufacturing process.

Hence, in view of the above, there exists a need for an end effector to address at least one of the above problems.

### SUMMARY

In accordance with a first aspect of the present invention there is provided a end effector for transferring a wafer, the end effector comprising a blade for supporting the wafer during transfer; and at least one engagement element coupled to the blade, the engagement element protruding from the blade for engaging the wafer during insertion of the blade into a wafer cassette for re-seating of the wafer in the cassette;

The engagement element may be adjustably coupled to the blade.

The engagement element may comprise a pusher block for pushing the wafer during insertion of the blade into the wafer cassette for the re-seating of the wafer.

The engagement element may comprise a rounded engagement surfaces for engaging the wafer.

The engagement element may comprise a Teflon material.

The end effector may further comprise one or more friction elements disposed on the blade for providing friction contact to the wafer during transfer.

One friction element may be disposed on the blade for providing friction contact substantially at a centre of the wafer during transfer.

The friction elements may comprise rubber O-rings.

The end effector may further comprise one or more raised boundaries disposed at a perimeter of the blade.

A width of the raised boundaries may be chosen so as to restrict lateral movement of the wafer during transfer.

The end effector may comprise a pair of said engagement elements, the engagement elements of the pair disposed substantially symmetrically with respect to an axis along an insert direction of the blade into the cassette.

The engagement element may be detachably coupled to the blade.

The end effector may further comprise a coupling element for coupling the end effector to a robotic arm.

In accordance with a second aspect of the present invention there is provided a method of re-seating a wafer in a wafer cassette, the method comprising, inserting of a blade of an end effector into the wafer cassette, and engaging the wafer during the inserting of the blade utilising an engagement element coupled to the blade.

The method may comprise pushing the wafer during the inserting of the blade into the wafer cassette for the re-seating of the wafer.

The method may comprise utilising a pair of engagement elements, the engagement elements of the pair disposed substantially symmetrically with respect to an axis along an insert direction of the blade into the cassette.

In accordance with a third aspect of the present invention there is provided a method of calibrating positioning of an end effector for wafer-pick, the method comprising clamping a dummy wafer on a blade of the end effector utilising an engagement element coupled to the blade; and inserting the blade into a wafer cassette up to a wafer-pick position in which further insertion of the blade is inhibited as a result of the clamped dummy wafer abutting a stopper element of the wafer cassette.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows an isometric top view of a robotic arm with an end effector.

FIG. 2 shows a plan view of the end effector of FIG. 1.

FIG. 3(a) shows an isometric top view of a wafer cassette.

FIG. 3(b) shows an isometric bottom view of the cassette of FIG. 3(a).

FIGS. 4(a) and (b) show a plan view and a sectional side view of a wafer cassette and end effector respectively, illustrating a method of re-sitting a wafer.

FIG. 5 shows a plan view of the cassette and end effector of FIGS. 4(a) and (b), illustrating the method of re-sitting the wafer.

FIGS. 6(a) and (b) show a plan view and a sectional side view of the wafer cassette and end effector of FIGS. 4(a) and (b), illustrating the method of re-sitting. FIG. 7 shows a photograph of a perspective top view of part of the end effector of FIG. 2.

FIG. 8 shows a technical drawing of an Isometric view of the end effector of FIG. 2.

FIG. 9 shows a flowchart illustrating a method of re-sitting a wafer in a wafer cassette.

FIGS. 10(a) and (b) show a plan view and a sectional side view of the wafer cassette and end effector, illustrating a method of calibrating positioning of the end effector for wafer-pick.

FIG. 11 shows a flowchart illustrating a method of calibrating positioning of an end effector for wafer-pick.

### DETAILED DESCRIPTION

The example embodiments described provide blade structures for robotic arm end effectors adapted to re-seat wafers in a cassette during end effector wafer pick.

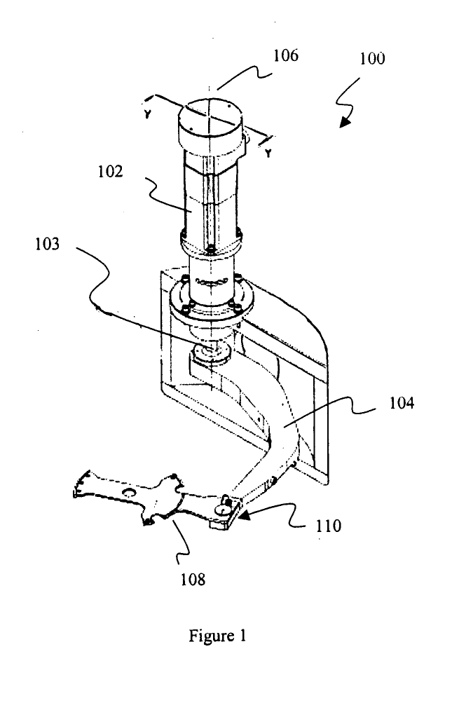

FIG. 1 shows a perspective isometric view of a robotic arm 100. The robotic arm 100 comprises a motor 102 and shaft 103, and a rotatable arm element 104. The arm 104 is coupled to the shaft 103 for rotation in a plane perpendicular to a vertical axis 106 of the shaft 103, and for relative movement about the axis 106.

An end effector in the form of a blade 108 is coupled to the free end 110 of the arm 104, for rotation in the plane of the arm 104, about axis 106.

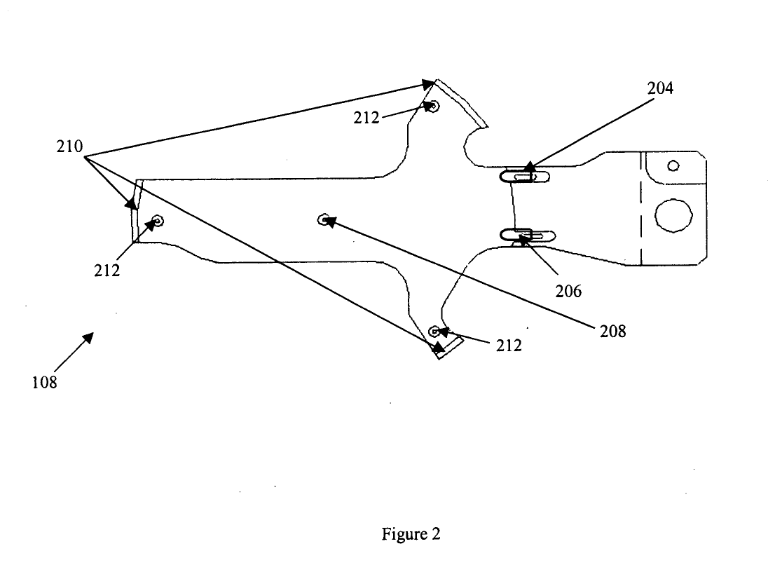

FIG. 2 shows a detailed plan view of the blade 108 disconnected from the arm 110 (FIG. 1). The blade 108 comprises adjustable blocks as wafer pushers 204, 206, an O-ring 208 disposed in the centre of the blade 108, blade fences e.g. 210 and O-rings e.g. 212 disposed on the peripheral of the blade 108. The O-rings form friction elements to provide a friction contact with the wafer during transfer.

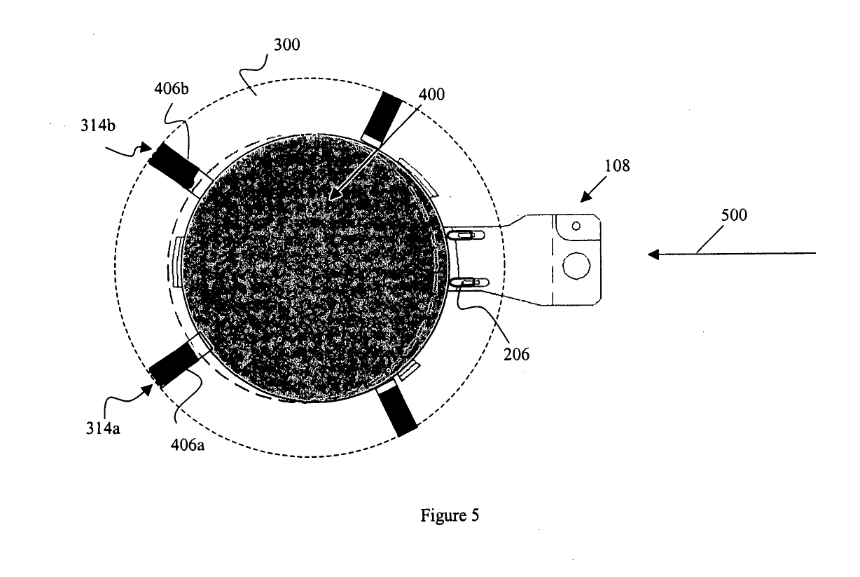

The wafer pushers 204, 206 form engagement elements and are used to “re-sit” an out-of-pocket wafer (not shown) during the wafer-pick process. “Re-sitting” is carried out so that the wafer does not rest on “abnormal or unsafe” positions on the blade 108 after the pick process. Details of the re-sitting step will be described below with reference to FIG. 4-6.

After pick-up, the wafer is further prevented from falling off the blade 108 by an increased height of the blade fences e.g. 210 compared to conventional blades. The blade fences e.g. 210 are also provided with a width such that there is a relatively small degree of freedom for the wafer to move about after the pick-up process. In addition, the wafer is frictionally restricted from movement on the blade 108 during transportation by the centre O-ring 208 and the O-rings e.g. 212 disposed on the peripheral of the blade 108.

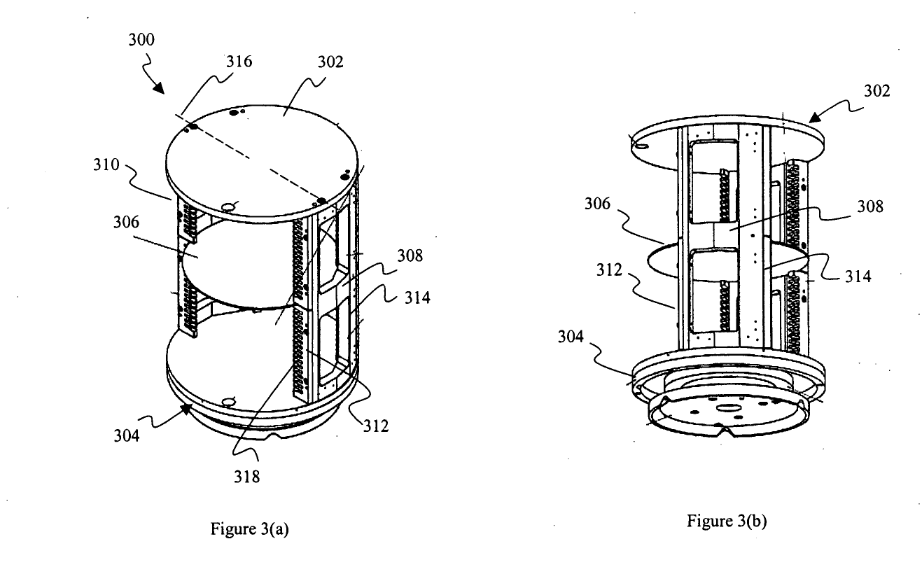

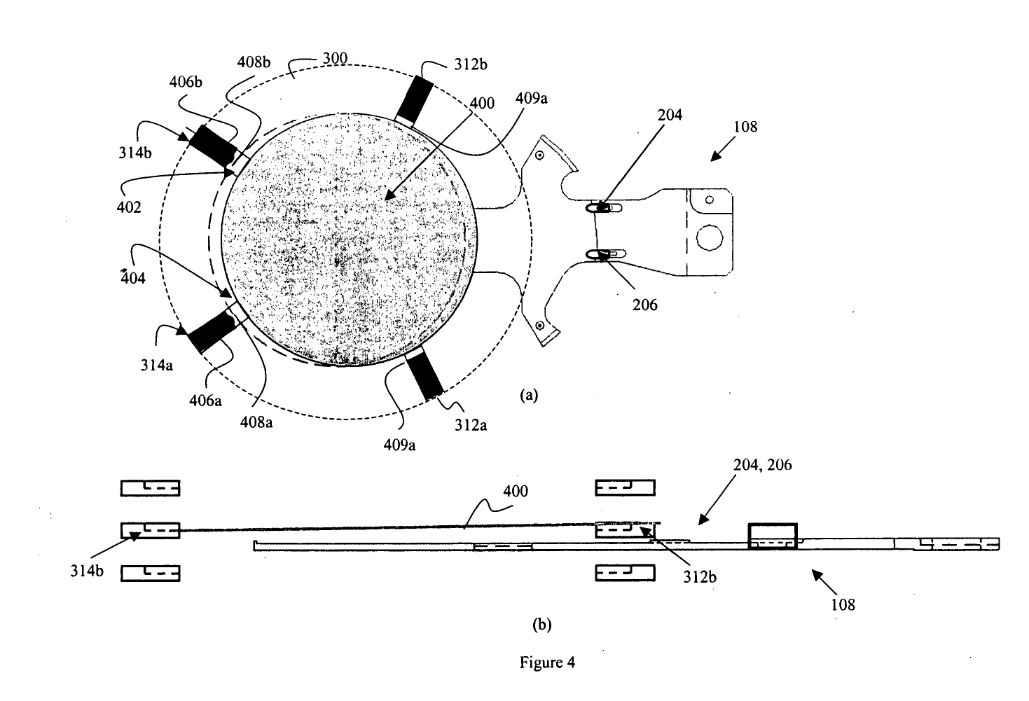

FIG. 3(a) shows an isometric top view of a wafer cassette 300 for receiving and storing wafers (not shown) at different stages during a wafer fabrication process. The cassette 300 comprises a circular top plate and bottom base 302, 304 respectively, as well as a circular partition 306 approximately half way along the height of the cassette 300. Two sidewall structures 308, 310 interconnect the top plate 302 and bottom base 304, as well as securing the partition 306. Each sidewall structure e.g. 308 provides a pair of mounting combs 312, 314. The sidewall structures e.g. 308 are disposed such that one of the combs 314, hereinafter referred to as a rear comb 314, is located at a longer distance from a mid-line 316 of the cassette 300, compared to the other comb 312, hereinafter referred to as a front comb 312. It will be appreciated by a person skilled in the art that therefore, the rear combs e.g. 314 provide a stopper element against which the wafers abut upon full insertion into the cassette 300, in addition to supporting the wafers in a vertically spaced apart manner.

On the other hand, the front combs e.g. 312 are configured for receiving the wafers therebetween during insertion of the wafers into the cassette 300. Therefore, if the wafers are fully inserted in the cassette 300, there remains a play between an outer circumference of the wafers and the vertical body of the front comb 312, with the teeths e.g. 318 providing support of the wafers in the vertically spaced apart manner. FIG. 3(b) shows a isometric bottom view of the cassette 300 for further clarity.

FIG. 4(a) is a top view diagram illustrating pick-up of a wafer 400 from the cassette 300. The blade 108 enters the cassette 300 to commence receiving of the wafer 400. The blade 108 passes between the front combs 312a, b and towards the rear combs 314a, b. As illustrated in FIG. 4(a) the wafer 400 does not sit fully inserted in the cassette 300, i.e. there are gaps 402, 404 between an outer periphery of the wafer 400 and the vertical main body 406a, b of the rear combs 314a, b respectively. At the same time, the wafer 400 remains supported by the teeth 408a, b of the rear combs 314a, b respectively, and by the teeth 409a, b of the front combs 312a, b respectively. FIG. 4(b) shows a schematic side view of FIG. 4(a) for further clarity.

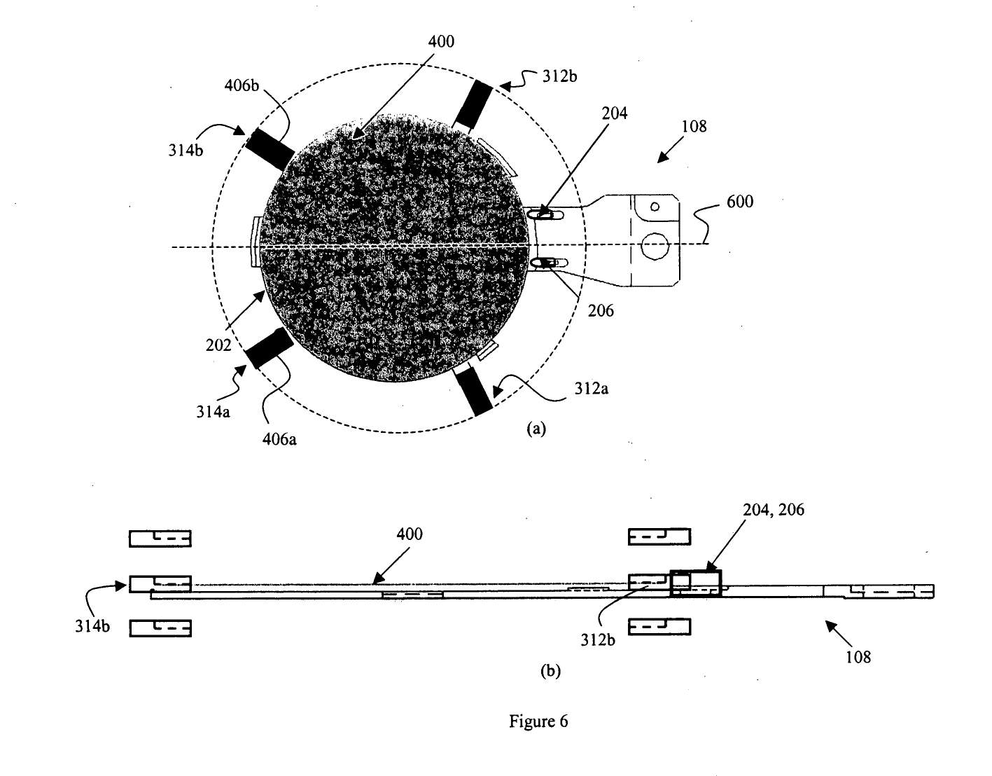

FIG. 5 is a plan view diagram with the blade 108 having entered further into the cassette 300 during the pick of the wafer 400. In the position as shown in FIG. 5, the wafer pushers 206 now abut the periphery of the wafer 400, thus engaging the wafer 400 during continued movement of the blade 108 into the cassette 300, along the direction indicated at 500. It will be appreciated by the person skilled in the art that during the continued insertion of the blade 108, the wafer 400 is re-seated in the cassette 300 by pushing the wafer 400 towards the vertical main body 406a, b of the rear combs 314a, b respectively.

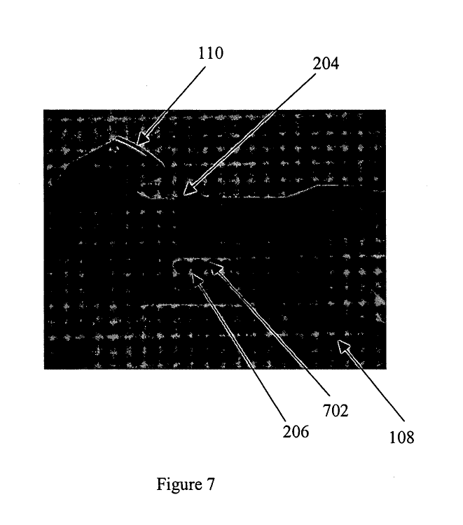

FIG. 6(a) is a plan view diagram showing the blade 108 in a final pick-up position, i.e. after the wafer 400 has been re-seated in the cassette 300. As can be seen from FIG. 6(a), the wafer 400 now abuts the vertical main body 406a, b of the rear combs 314a, b respectively. Furthermore, it will be appreciated by the person skilled in the art that since the blade 108 enters the cassette 300 substantially along a centre-line 600 between the rear combs 314a, b and the front combs 312a, b, the pushing of the wafer 400 through the engagement with the wafer pushers 204, 206 results in a re-sitting substantially in a fully inserted position of the wafer 400 in the cassette 300. Accordingly, the described arrangement can advantageously provide a blade 108 suitable for performing a re-sitting of wafers which are displaced from a fully inserted position within the cassette 300 during the pick operation. The re-sitting of the wafers can ensure that the wafers will rest in a normal or safe position on the blade 108 after receiving by lowering the cassette 300 and retraction of the blade 108 from the cassette 300, thereby reducing the occurrence of wafer slip off the blade during transfer. FIG. 6(b) shows a side view of FIG. 6(a) for clarity.

FIG. 7 is a photograph showing the wafer pushers 204, 206 attached to the blade 108. The wafer pushers 204, 206 are adjustable to accommodate tool-to-tool variation and are also adjustable for ease of blade-to-cassette alignment and calibration. The wafer pushers 204, 206 have rounded contact surfaces to reduce mechanical stress when in physical contact with the wafer periphery. The wafer pushers 204, 206 comprise plastic material such that the hardness factor of the wafer pushers is less than the hardness factor of typical wafers. The wafer pushers 204, 206 are mounted on the blade 108 by screws e.g. 702.

The blade 108 is preferably provided with a central blade thickness of about 3.2 mm by mechanical polishing. By “thinning” the blade 108 from a thickness of about 3.67 mm, blade fences e.g. 210 are provided with a relatively taller height compared to existing blade designs. These higher blade fences 210 can advantageously further prevent the wafer from slipping off the blade 108 during wafer transfer/transportation since the top of the fences e.g. 210 are above the wafer surface.

In addition, the blade fences 210 are provided with a relatively larger width compared to existing blade designs. The blade fences 210 have width of about 3 mm, compared to 1 mm in existing designs. Therefore, a reduced support diameter between the blade fences 210 of about 202 mm (compared to 206 mm in existing designs) is provided, for an actual wafer diameter of 200 mm. A larger blade fence width for the blade fences 210 advantageously reduces the available gap between the wafer and the blade fences 210, thus reducing the freedom of the wafer movement on the blade 108, ensuring the wafer is kept within the gripping tolerance of the transfer arm during the subsequent stage of transfer/transportation.

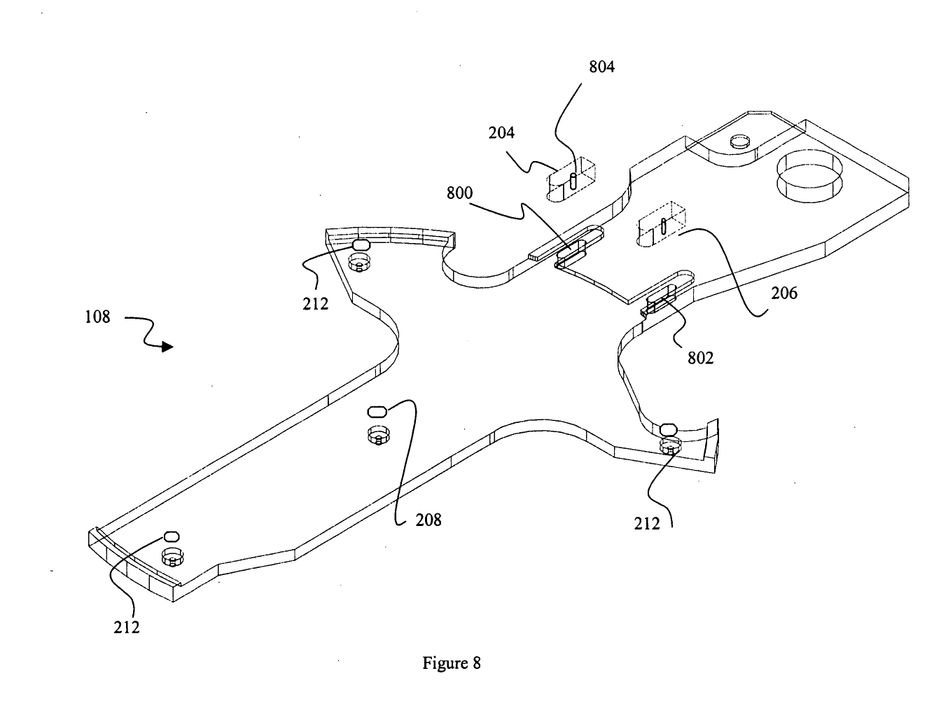

FIG. 8 shows an isometric view of the blade 108 and the wafer pushers 204, 206. Slots 800, 802 are provided in the blade 108 underneath the wafer pushers 204, 206 for adjustably mounting the wafer pushers 204, 206 on the blade 108, utilising a screw (not shown) received in a threaded through-hole 804 in the wafer pushers 204, 206. The O-rings 212 are provided at different locations along the periphery of the blade 108. The O-rings 212 provide frictional contact between the blade 108 and the wafer, during transportation of the wafer. The centre O-ring 208 is provided, to advantageously further increase the friction contact. The O-rings 212, 208 are mounted on the blade 108 by press fit.

The described arrangement improve wafer handling by “re-sitting” out-of-pocket wafers during the wafer-pick process without an additional or independent wafer alignment sequence or system. Wafer handling is also improved by enhancing the wafer retention capability of the end effector by providing higher and wider blade fences and additional O-rings. The arrangement prevents wafer scrapped due to wafer slip during transfer of the wafers by preventing wafers from slipping outside of the transfer arm gripping tolerance during the transfer sequence from the end effector to the processing stations. Wafer scrapped is also prevented by the blade fences, which prevent wafers from slipping off the blade during transfer.

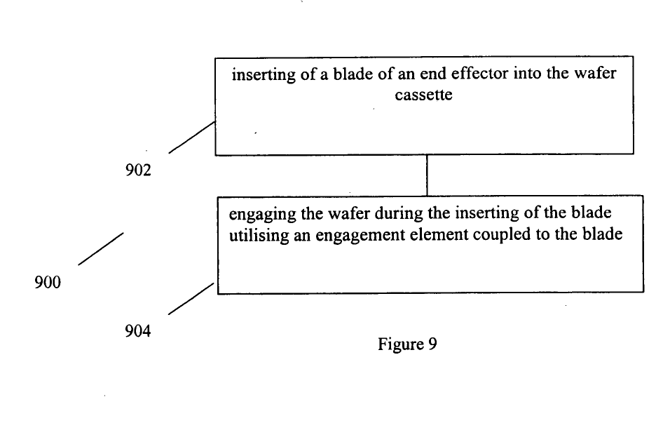

FIG. 9 shows a flowchart 900 illustrating a method of re-sitting a wafer in a wafer cassette. At step 902, a blade of an end effector is inserted into the wafer cassette. At step 904, the wafer is engaged during the inserting of the blade utilising an engagement element coupled to the blade.

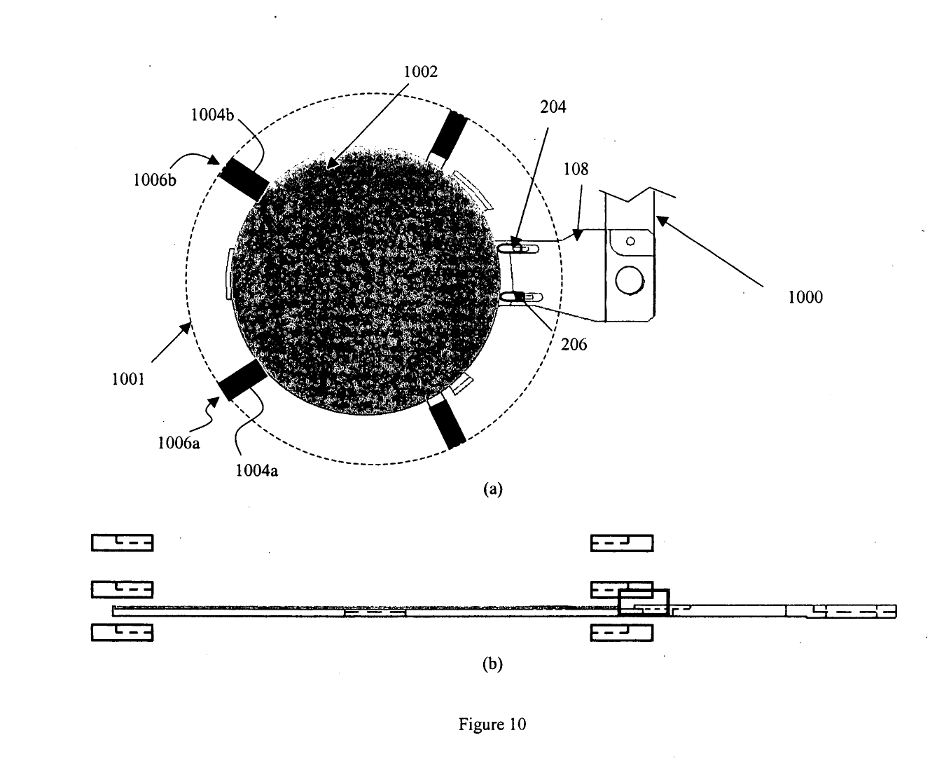

Furthermore, the described arrangement facilitate an easier calibration process, potentially reducing calibration time. The arrangement can be used during the calibration of positioning of an end effector for wafer-pick from a wafer cassette. With reference to FIG. 10, during the calibration the robot arm 1000 is manually operated to insert the blade 108 into the wafer cassette 1001, with a dummy wafer 1002 positioned on the blade 108. In the modified calibration process using the blade 108, the wafer pushers 204, 206 are adjusted such that they clamp the dummy wafer 1002 against the blade fence 210 at the end of the blade 108. The blade 108 is manually inserted into the cassette until the dummy wafer 1002 abuts the vertical main body 1004a, b of the rear combs 1006a, b, respectively, acting as stopper elements.

At that point, further insertion of the blade 108 is prevented due to the clamping of the dummy wafer 1002 by the wafer pushers 204, 206 on the one hand, and the dummy wafer 1002 abutting the vertical main body 1004a, b on the other hand. This facilitates determination/calibration of the blade position for wafer-pick. With existing blade designs, the wafer-pick position of the blade must be judged based purely on visual alignment of the blade and the dummy wafer. Once the blade 108 has been moved into the wafer-pick position, the positioning parameters are read and entered into the control system for automated wafer-pick.

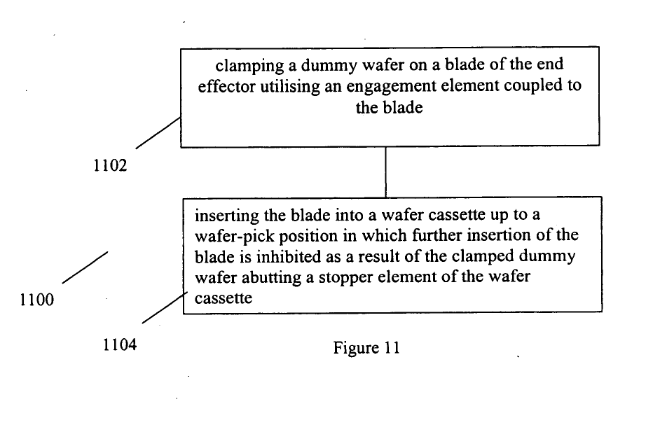

FIG. 11 shows a flowchart 1100 illustrating a method of calibrating positioning of an end effector for wafer-pick. At step 1102, a dummy wafer is clamped on a blade of the end effector utilising an engagement element coupled to the blade. At step 1104, the blade is inserted into a wafer cassette up to a wafer-pick position in which further insertion of the blade is inhibited as a result of the clamped dummy wafer abutting a stopper element of the wafer cassette.

It will be appreciated by a person skilled in the art that numerous variations and/or modifications may be made to the present invention without departing from the spirit or scope of the invention as broadly described. The described arrangements are, therefore, to be considered in all respects to be illustrative and not restrictive.

For example, although the wafer pushers have been described as comprising rounded contact surfaces, the wafer pushers may be in other shapes such as, but not limited to, having concave contact surfaces. Also, although the wafer pushers have been described as a pair of attachments, other configurations may also apply such as, but not limited to, utilizing a bar with a curvature or a single wafer pusher.

In addition, although the wafer pushers have been described as being attached to the blade by screws, other bonding devices such as, but not restricted to, rivets, clips or bonding glue may be used. The wafer pushers may also be provided on the blade by manufacturing techniques such as molding.

Also, although plastic has been described as the material for manufacturing the wafer pushers, other materials may also be used.

1. An end effector for transferring a wafer, the end effector comprising,
a blade for supporting the wafer during transfer; and
at least one engagement element coupled to the blade, the engagement element protruding from the blade for engaging the wafer during insertion of the blade into a wafer cassette for re-seating of the wafer in the cassette.

2. The end effector as claimed in claim 1, wherein the engagement element is adjustably coupled to the blade.

3. The end effector as claimed in claim 1, wherein the engagement element comprises a pusher block for pushing the wafer during insertion of the blade into the wafer cassette for the re-seating of the wafer.

4. The end effector as claimed in claim 1, wherein the engagement element comprise a rounded engagement surfaces for engaging the wafer.

5. The end effector as claimed in claim 1, wherein the engagement element comprises a Teflon material.

6. The end effector as claimed in claim 1, further comprising one or more friction elements disposed on the blade for providing friction contact to the wafer during transfer.

7. The end effector as claimed in claim 6, wherein one friction element is disposed on the blade for providing friction contact substantially at a centre of the wafer during transfer.

8. The end effector as claimed in claim 6, wherein the friction elements comprise rubber O-rings.

9. The end effector as claimed in claim 1, further comprising one or more raised boundaries disposed at a perimeter of the blade.

10. The end effector as claimed in claim 9, wherein a width of the raised boundaries is chosen so as to restrict lateral movement of the wafer during transfer.

11. The end effector as claimed in claim 1, comprising a pair of said engagement elements, the engagement elements of the pair disposed substantially symmetrically with respect to an axis along an insert direction of the blade into the cassette.

12. The end effector as claimed in claim 1, wherein the engagement element is detachably coupled to the blade.

13. The end effector as claimed in claim 1, further comprising a coupling element for coupling the end effector to a robotic arm.

14. A method of re-seating a wafer in a wafer cassette, the method comprising,
inserting of a blade of an end effector into the wafer cassette, and
engaging the wafer during the inserting of the blade utilising an engagement element coupled to the blade.

15. The method as claimed in claim 14, comprising pushing the wafer during the inserting of the blade into the wafer cassette for the re-seating of the wafer.

16. The method as claimed in claim 14, comprising utilising a pair of engagement elements, the engagement elements of the pair disposed substantially symmetrically with respect to an axis along an insert direction of the blade into the cassette.

17. A method of calibrating positioning of an end effector for wafer-pick, the method comprising,
clamping a dummy wafer on a blade of the end effector utilising an engagement element coupled to the blade; and
inserting the blade into a wafer cassette up to a wafer-pick position in which further insertion of the blade is inhibited as a result of the clamped dummy wafer abutting a stopper element of the wafer cassette.
